(19) United States
(12) Patent Application Publication
(10) Pub. No.: US 2018/0235406 A1
(43) Pub. Date: Aug. 23, 2018

(54) BATH PLUG

(71) Applicants: Liam Thomas O'Reilly, Heathridge (AU); Edward Joseph Khoury, Bateman (AU)

(72) Inventors: Liam Thomas O'Reilly, Heathridge (AU); Edward Joseph Khoury, Bateman (AU)

(21) Appl. No.: 15/752,197

(22) PCT Filed: Aug. 5, 2016
(86) PCT No.: PCT/AU2016/050707

§ 371 Date: Feb. 12, 2018

(30) Foreign Application Priority Data
Aug. 12, 2015 (AU) 2015903236

(51) Int. Cl. A47K 1/14; A47K 3/00; E03C 1/23; H03K 17/28

(52) U.S. Cl. CPC A47K 1/14; A47K 3/001; G04F 1/005; H03K 17/28; E03C 2001/2311; E03C 1/23

(57) ABSTRACT

A plug (10) comprising a body (12) having a base portion (22) and an upper portion (24), the base portion (22) being receivable in an outlet (14) of a bath to prevent water flow. An actuator (42) is provided within the body (12) being moveable from a retracted position to an extended position. A timer is operable such that when a time period has elapsed from activation of the timer, the actuator (42) moves from the retracted to the extended position. In the extended position, the actuator (42) moves the body (12) of the plug (10) to disengage the plug (10) from the outlet (14) such that water may flow outwardly through the outlet (14).

### FIELD OF THE INVENTION

The present invention relates to a plug for a bath.

### BACKGROUND TO THE INVENTION

Drowning in a bathtub is a significant risk for small children, even in relatively low levels of water. While some drownings occur due to children being left briefly unattended in a bath, drowning can also occur simply by leaving water in the bathtub after use. During the process of removing a child from a bath and getting them dried and dressed, it is possible for the carer to simply forget to remove the plug. This then leaves open the possibility of a small child entering the bathroom and falling into the bathtub.

Plugs have been proposed incorporating a timer which causes the water to be released from the bath after a specified time. Such plugs may comprise either devices built into outlet or separate plugs having some type of opening valve. The present invention relates to a plug for a bathtub aimed at providing automatic release of water from a bath in a form which is effective, reliable and easy to use.

### SUMMARY OF THE INVENTION

According to one aspect of the present invention there is provided a plug comprising:

a body being receivable in relation to an outlet of a bath to prevent water flow;
an actuator within the body moveable from a retracted position to an extended position; and
a timer operable such that when a time period has elapsed from activation of the timer, the actuator moves from the retracted to the extended position; wherein in the extended position, the actuator moves the body of the plug to disengage the plug from the outlet such that water may flow outwardly through the outlet.

In a preferred embodiment, the body includes a base portion receivable in the outlet and an upper portion located in use above the outlet.

Preferably the actuator comprises a shaft provided within a chamber in the base portion of the body such that, in the extended position, a first end of the shaft protrudes outwardly through a port in the base portion.

Preferably the first end of the shaft includes an angled portion to engage with an upper edge of a cylindrical outer wall of the outlet to lift the body of the plug relative to the outlet.

In a preferred embodiment, the angled portion comprises a planar face such that, in the extend position, an upper edge thereof is located further away from the base portion than a lower edge thereof.

Preferably the base portion comprises a cylindrical side wall and a circular base wall and wherein the shaft is located adjacent and parallel to the base wall and the port is provided in the side wall.

In a preferred embodiment, the plug further comprises:

a drive motor provided within an upper portion of the chamber; and a gear wheel provided on a drive shaft of the drive motor, the gear wheel being located adjacent the shaft;
wherein teeth on the gear wheel engage with notches provided in a side of the shaft such that operation of the drive motor rotates the gear and thereby causes translational movement of the shaft between the retracted and extended positions.

Preferably the base portion and the upper portion of the body are cylindrical in shape and a lower end of the upper portion is wider than the base portion such that a shoulder portion is defined between the base portion and upper portion, the shoulder portion resting on top of a rim of the outlet to prevent flow of fluid.

Preferably a button is provided such that operation of the button causes the shaft to move from the extended position to the retracted position and operation of the timer to commence.

In one embodiment, an upper end of the upper portion includes cut out portions on opposed upper sides thereof defining first planar wall portions extending vertical downwardly from an upper end of the upper portion on opposed sides of the upper portion, and second planar wall portions extending horizontally outwardly from lower ends of the first planar wall portions.

Preferably the start button is provided on one of the second planar wall portions.

In one embodiment, the time period of operation may be selected by multiple presses of the button and a plurality of indicator lights are provided to indicate the time period which has been selected.

In one embodiment, the indicator lights are provided on the second planar wall portion alongside the start button

In one embodiment, the upper portion is provided with a cover extending across and sealing over the upper portion of the body such that the body of the plug is waterproof.

Preferably the cover comprises a flexible resilient material and extends around a lower end of the upper portion of the body across the shoulder portion to engage against and seal the outlet.

Preferably one or more seals are provided adjacent the first end of the shaft to engage between an inner surface of the port and an outer surface of the shaft to prevent ingress of water through the port into the chamber.

Preferably the plug includes a battery to power movement of the actuator and a base wall of the base portion is provided with contacts to engage with contacts in a cradle of a charging device when the plug is placed in the cradle in order to charge the battery.

In one embodiment, a temperature sensor is provided to sense the temperature of the water within the bath and an alert is provided to indicate that the temperature of the water is above a particular value.

In one embodiment, the body has a density near to or below that of water such that motion of the actuator to the extended position is sufficient to cause the plug to move upwardly and away from the outlet.

In one embodiment, the plug includes a motion sensor to sense movement within the bath, the motion sensor being in communication with the timer such that the time period before the actuator is extended is set to commence when no motion is detected within the bath.

In accordance with a second aspect of the present invention, there is provided a plug comprising:

a body being receivable in relation to an outlet of a bath to prevent water flow; a timer operable such that when a time period has elapsed from activation of the timer, the body or a portion of the body is disengaged from the outlet to allow water to flow through the outlet; and
a motion sensor provided to detect movement within the bath;
wherein the time period before the body or the portion of the body is disengaged from the outlet commences when no motion is detected within the bath.

### BRIEF DESCRIPTION OF THE DRAWINGS

The invention will now be described, by way of example, with reference to the following drawings, in which:

FIG. 1a is an upper perspective view of a plug in accordance with the present invention;

FIG. 1b a lower perspective view of the plug of FIG. 1a;

FIG. 2a is a top view of the plug of FIG. 1;

FIG. 2b is a side view of the plug of FIG. 1;

FIG. 3 is a first exploded view of the plug of FIG. 1;

FIG. 4 is a second exploded view of the plug of FIG. 1;

FIG. 5a is a top view of the plug of FIG. 1;

FIG. 5b is a cross sectional view of the plug of FIG. 5a through the line B-B;

FIG. 8a is a top view of the plug of FIG. 1;

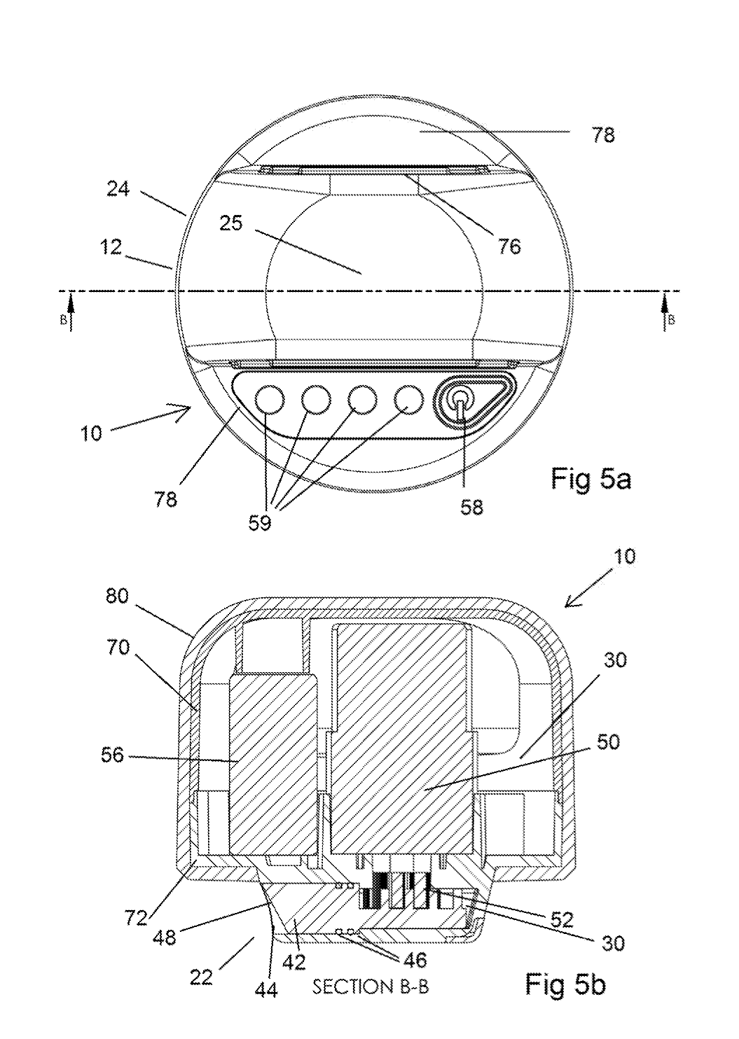

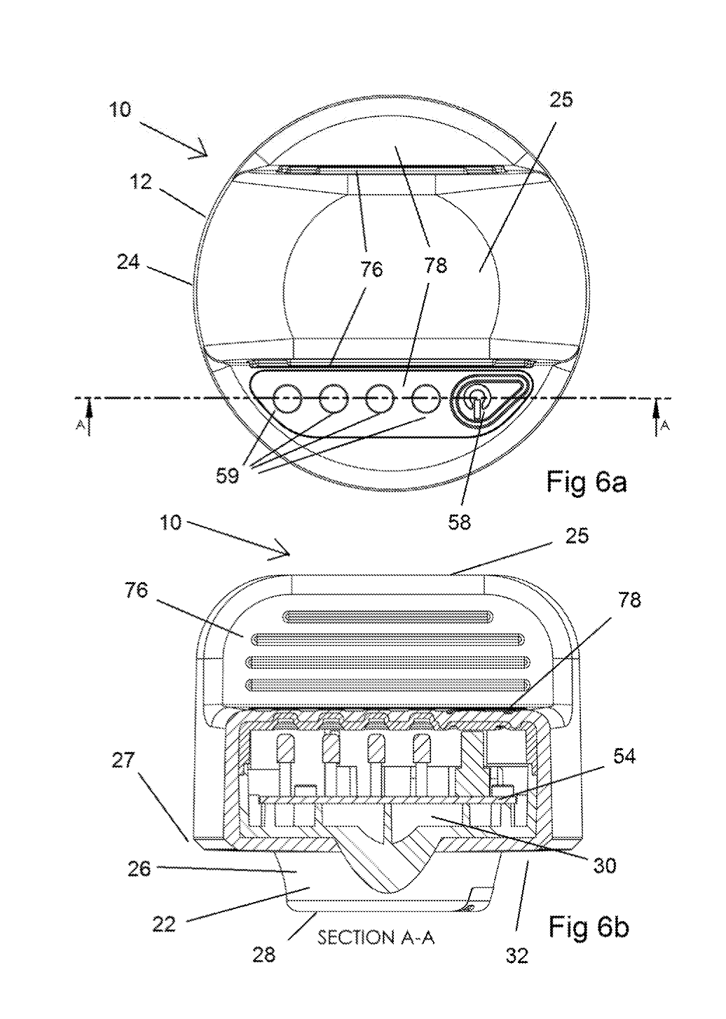

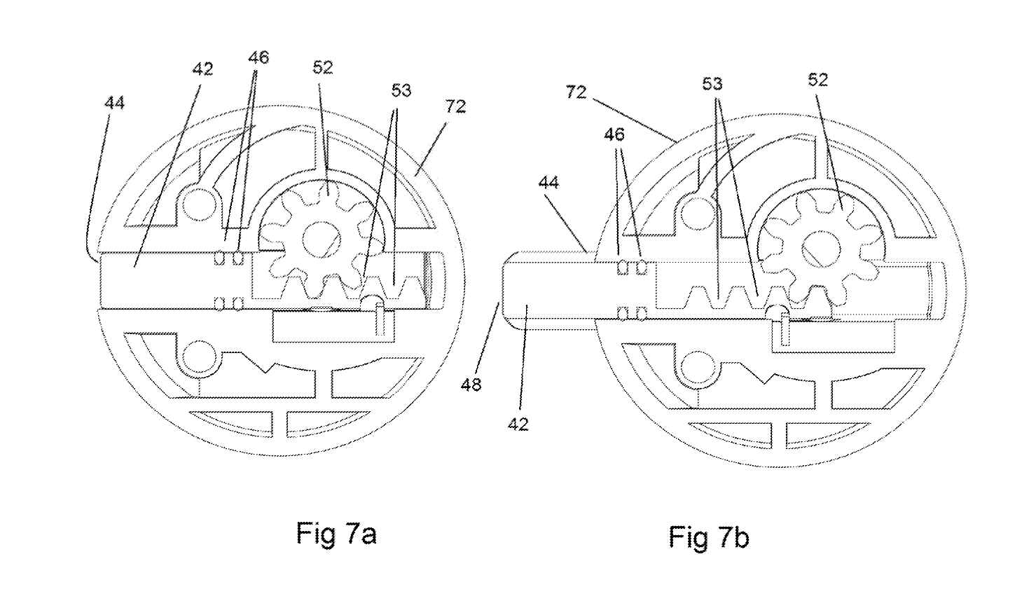

FIG. 6b is a cross sectional view of the plug of FIG. 5a through the line A-A;

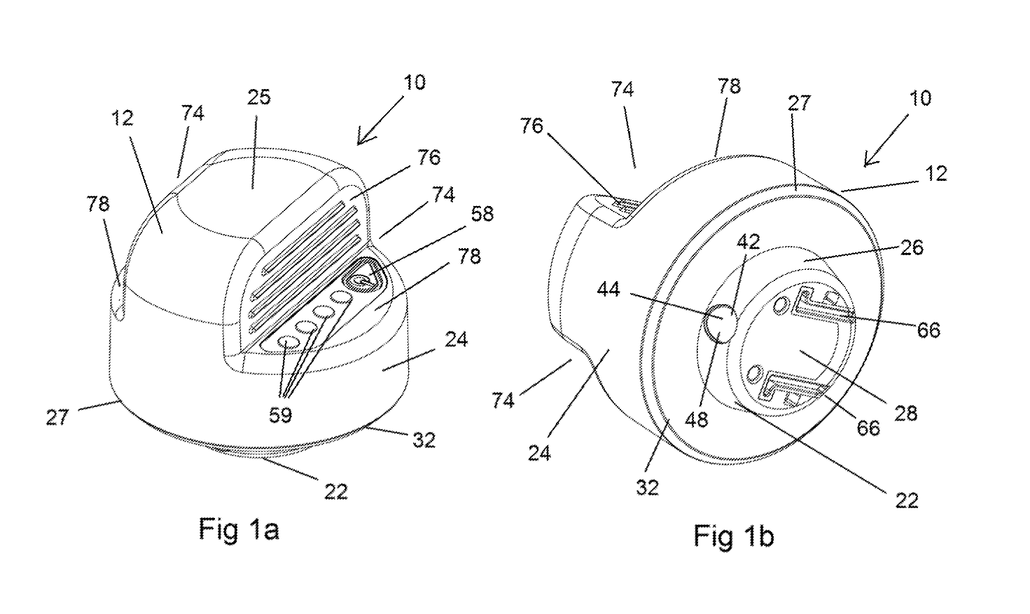

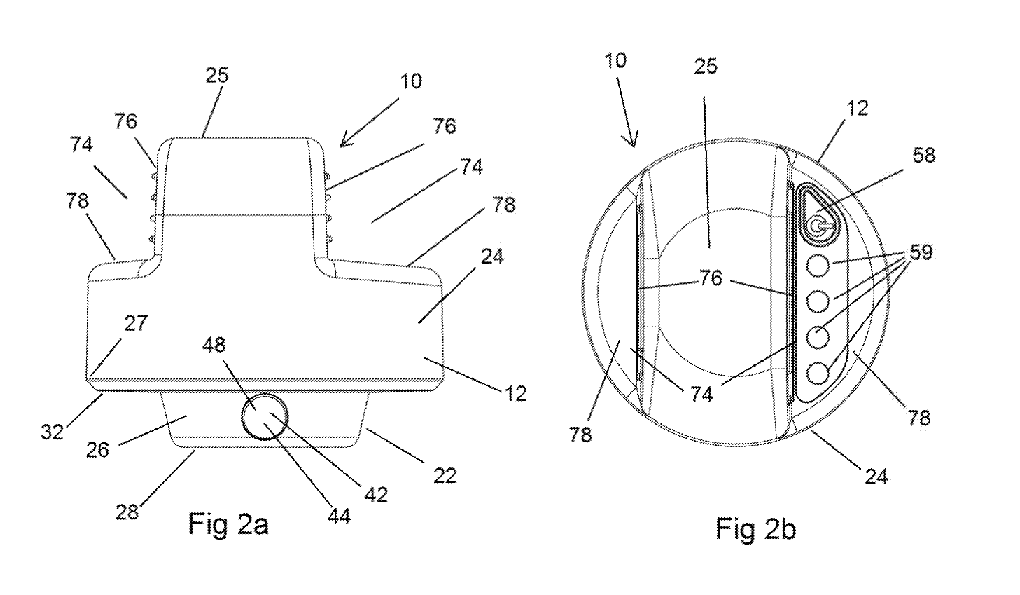

FIG. 7a is a top cross sectional view of the plug of FIG. 1 showing the shaft in a retracted position;

FIG. 7b is a top cross sectional view of the plug of FIG. 1 showing the shaft in an extended position;

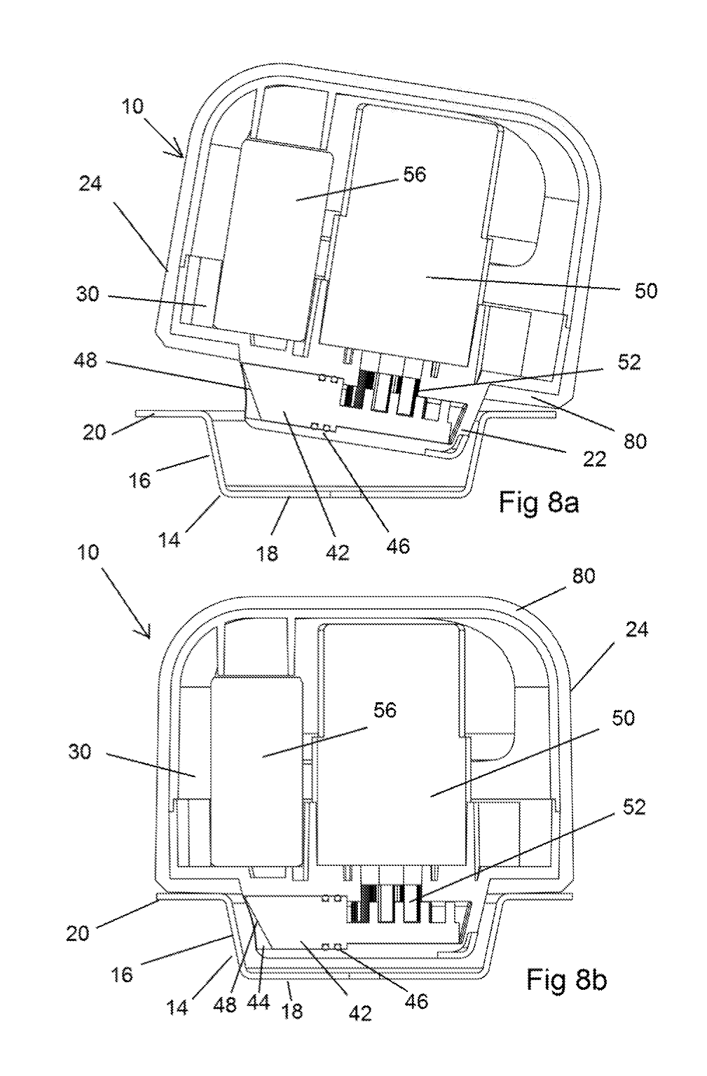

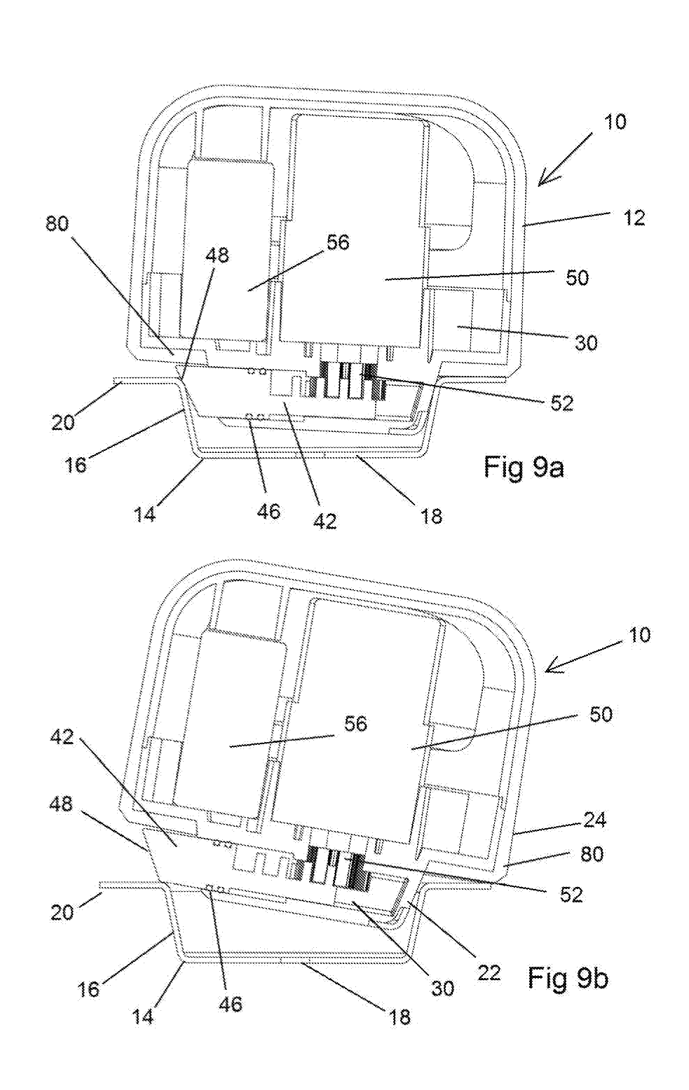

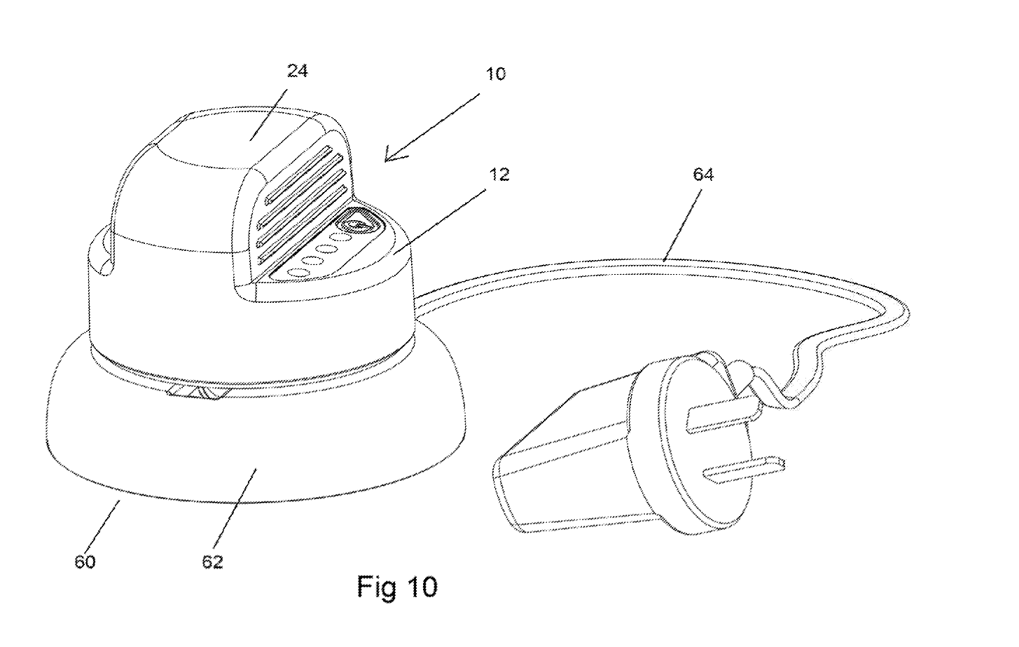

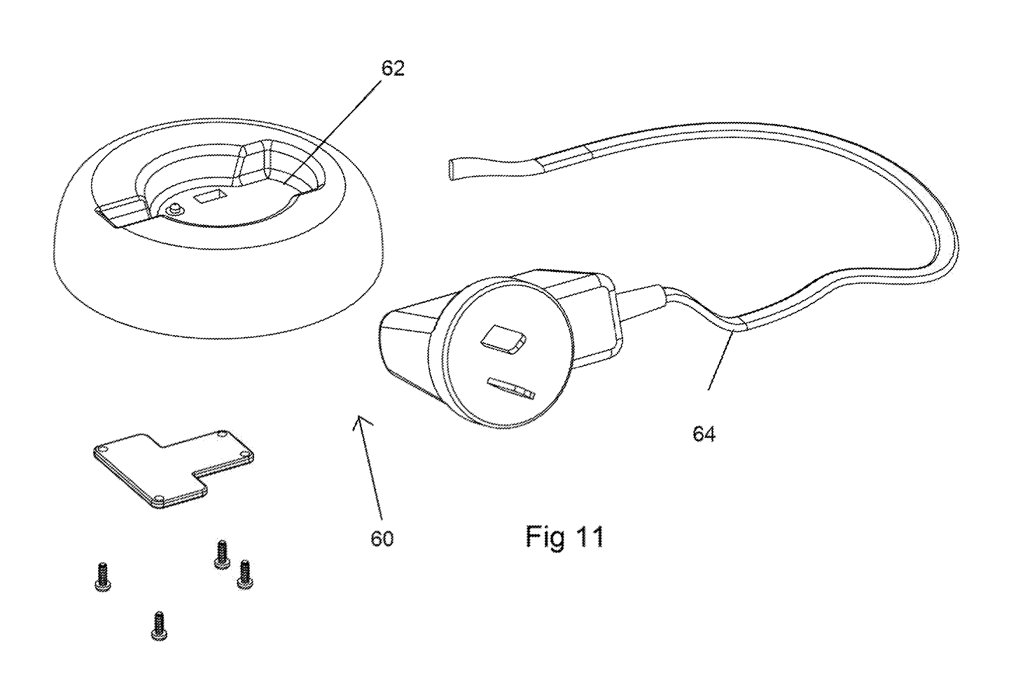

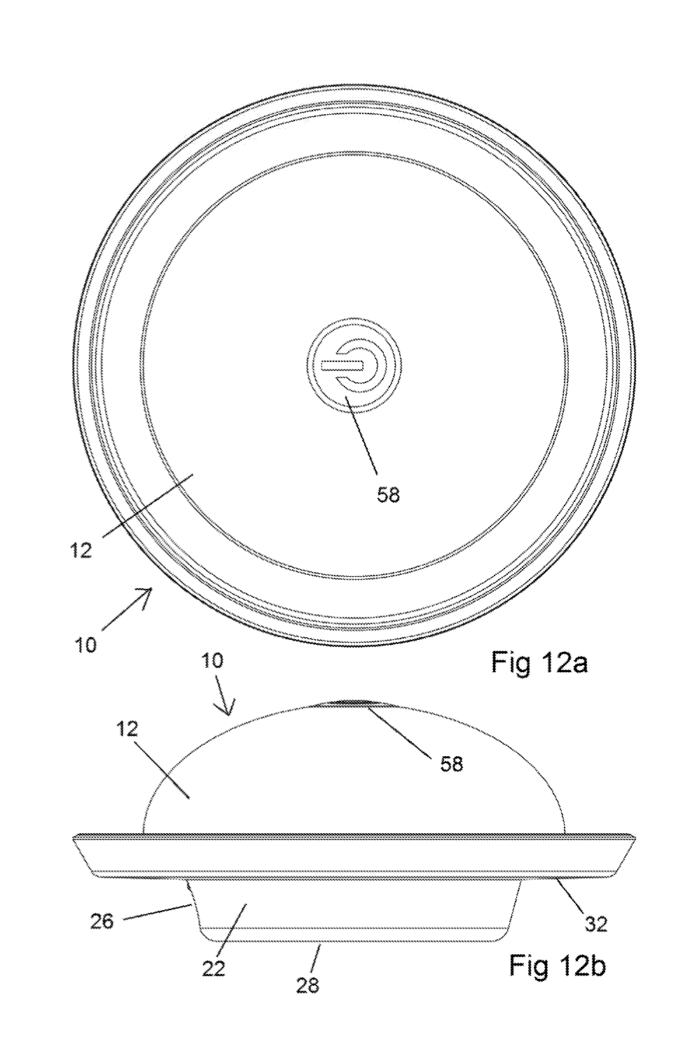

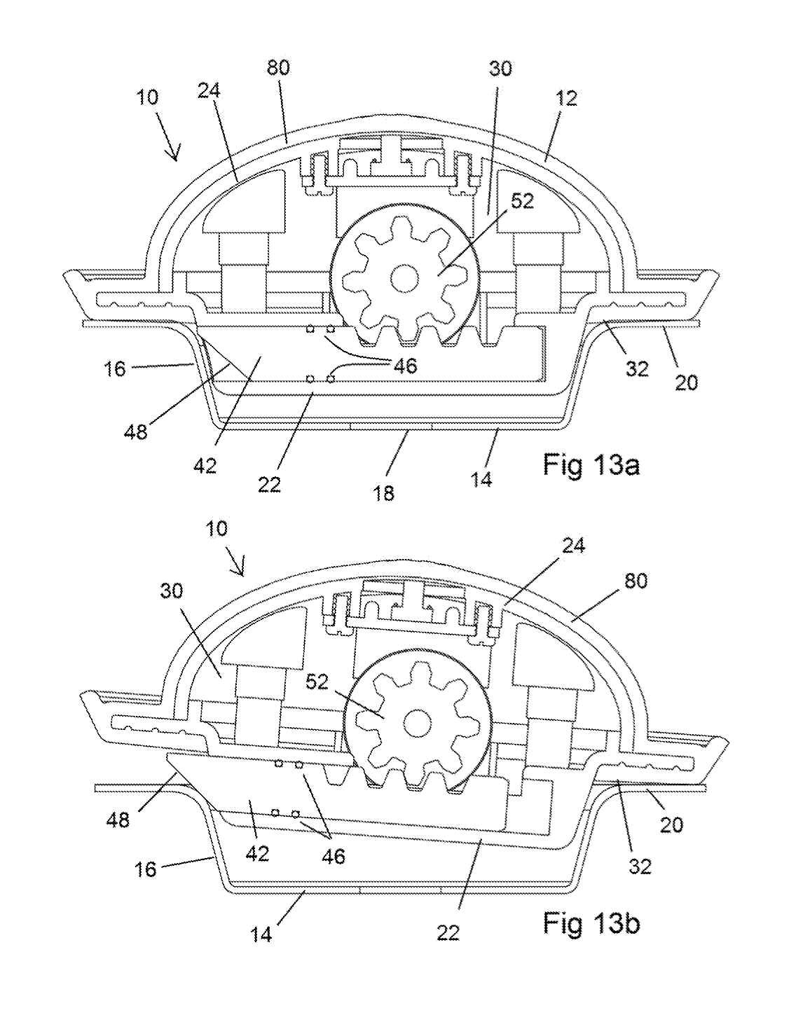

FIG. 8a is a side cross sectional view of the plug of FIG. 1 prior to operation above an outlet;

FIG. 8b is a side cross sectional view of the plug of FIG. 1 showing the plug in place in the outlet;

FIG. 9a is a side cross sectional view of the plug of FIG. 1 showing the shaft moving to engage with an edge of the outlet;

FIG. 9b is a side cross sectional view of the plug of FIG. 1 showing the shaft engaged with the edge of the outlet to lift the plug and disengage the plug from the outlet;

FIG. 10 is a view of the plug of FIG. 1 in place on a charging device;

FIG. 11 is an exploded view of the charging device;

FIG. 12a is a top view of a second embodiment of a plug in accordance with the present invention;

FIG. 12b is a side view of the plug of FIG. 12a;

FIG. 13a is a side cross sectional view of the plug of FIG. 12 showing the plug engaged with the outlet and the shaft retracted; and

FIG. 13b is a side cross sectional view of the plug of FIG. 12 showing the shaft extended to disengage the plug from the outlet.

### DETAILED DESCRIPTION OF PREFERRED EMBODIMENTS

Referring to the Figures, there is shown a plug 10 comprising a body 12 to be used in relation to an outlet 14. The outlet 14 comprises a standard drain outlet of the type that may be found in a bathtub (as can be seen in FIGS. 8 and 9). The outlet 14 comprises a tapered cylindrical outer wall 16 having a grate 18 extending across a lower end thereof. An annular rim 20 extends from around an upper edge of the outer wall 16.

The body 12 of the plug 10 comprises generally a base portion 22 and an upper portion 24. The base portion 22 is provided to be received within the outlet 14 of the drain and the upper portion 24 sits, in use, above the outlet 14. The base portion 22 is therefore cylindrical in shape of a diameter less than that of the outlet in which it is to be used. In the embodiment shown, the upper portion 24 is also generally cylindrical. It will be appreciated however that other shapes may be employed for the upper portion 24. The body defines an internal chamber 30.

The base portion 22 comprises a tapered cylindrical side wall 26 and a base wall 28 extending across a lower end of the side wall 26. The base portion 22 is dimensioned to be received in the outlet 14 such that the side wall 26 is located within the outer wall 16 and the base wall 28 is located adjacent the grate 18.

A lower end 27 of the upper portion 24 is wider than the base portion 22 such that a shoulder portion 32 is defined between the base and upper portions 22 and 24. The shoulder portion 32 rests on top of the rim 20, as can be seen in FIG. 8b, such that the shoulder portion 32 of the plug 10 closes across the outlet 14 to prevent flow of fluid outwardly through the outlet 14.

The upper portion 24 in the embodiment shown is cylindrical in shape, being larger in diameter than the base portion 22. An upper end 25 of the upper portion 24 includes cut out portions on opposed upper sides thereof. The cut out portions 74 define first planar wall portions 76 extending vertically downwardly from the upper end 25 of the upper portion 24, on opposed sides of the upper portion 24, and second planar wall portions 78 extending horizontally outwardly from lower ends of the first planar wall portions 76. The opposed first planar wall portions 76 may be used to grip and lift the plug 10 by the upper portion 24.

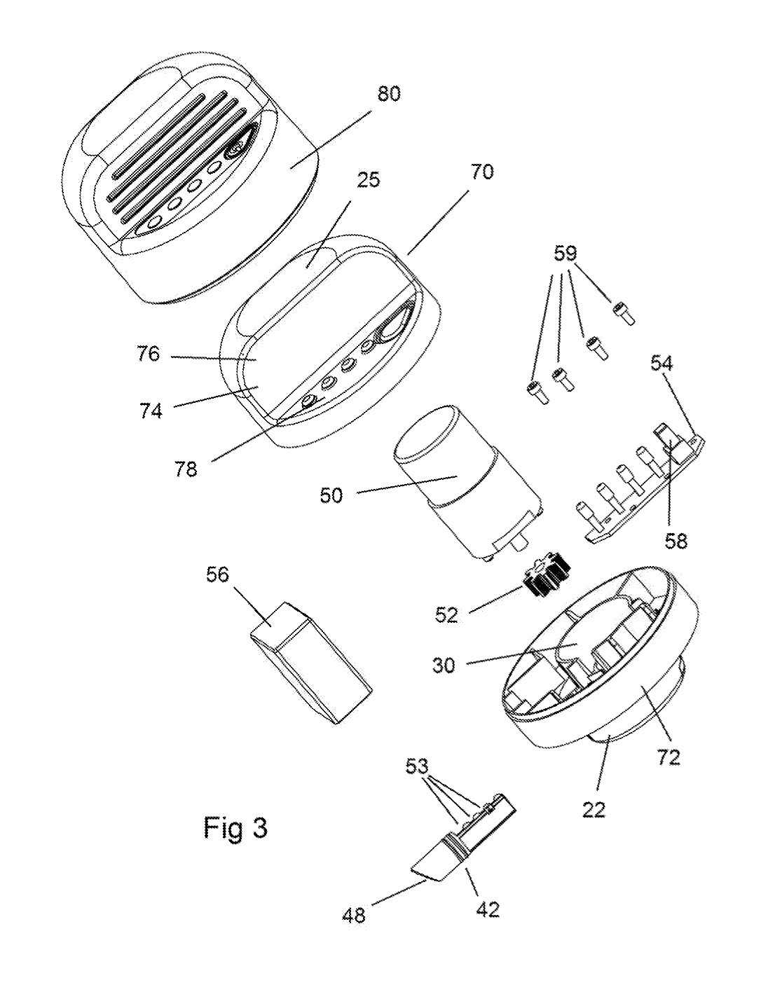

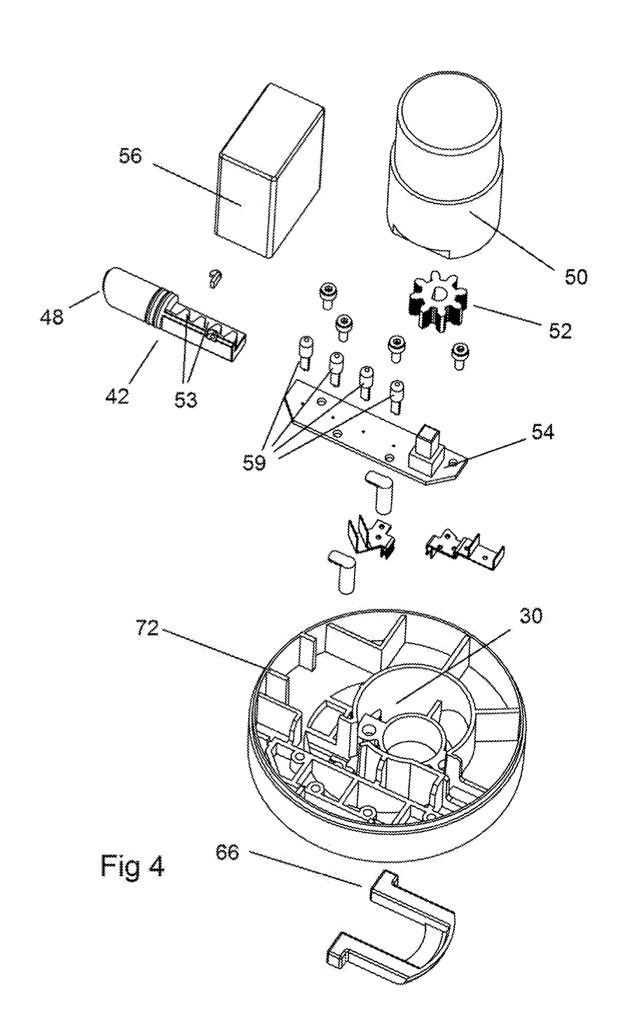

In the embodiment shown, the body 12 comprises an upper casing portion 70 and a lower casing portion 72 (as can be seen in FIGS. 3 and 4). The lower casing portion 72 comprises the base portion 22 of the body 12 and a lower end of the upper portion 24. The upper casing portion 70 is secured to the lower casing portion 72 to define the upper portion 24 of the body 12.

The plug 10 is provided with an actuator 40. The actuator 40 is provided to move the plug 10 such that on operation of the actuator 40, water may flow outwardly through the outlet 14. In the embodiment shown, the actuator 40 is provided to move the body 12 of the plug 10 from an engaged position (as shown in FIG. 8b) in which the outlet 14 is obstructed, to a disengaged position (as shown in FIG. 9b) in which the body 12 of the plug 10 is moved upwardly such that water may flow downwardly through the outlet 14.

In the embodiment shown, the actuator 40 comprises a shaft 42 provided within the portion of the chamber 30 within the base portion 22. A port 44 is provided in the side wall 26 of the base portion 22. The shaft 42 is located adjacent and parallel to the base wall 28 of the base portion 22 and a first end thereof is received within the port 44. The shaft 42 is provided with one or more seals 46 adjacent the first end thereof. The seals 46 engage between an inner surface of the port 44 and an outer surface of the shaft 42 to prevent ingress of water through the port 44 into the chamber 30.

The shaft 42 is movable between a retracted position (as shown in FIG. 7a) and an extended position (as shown in FIG. 7b). In the retracted position, the first end of the shaft 42 is located within the extents of the side wall 26 of the base portion 22. In the extended position, the first end of the shaft 42 protrudes beyond the side wall 26.

The first end of the shaft 42 includes an angled portion 48. The angled portion 48 is provided to engage the outer wall 16 of the outlet 14 adjacent an upper edge thereof. The angled portion 48 comprises a planar face such that, in the extend position, an upper edge thereof is located further away from the base portion 22 than a lower edge thereof. The engagement is such that as the shaft 42 moves to the extended position, the angled face 48 rides up over the upper edge of the outer wall 16 of the outlet 14. The body 12 of the plug 10 is thereby moved upwardly away from the outlet 14 and the shoulder portion 32 disengages from the rim portion 20 (as can be seen in FIG. 9) allowing water to flow downwardly through the outlet 14.

The shaft 42 is moved between the retracted and extended positions by a drive motor 50. The drive motor 50 is mounted within an upper portion of the chamber 30, within the upper portion 24 of the body 12. The drive motor 50 in the embodiment shown includes a drive shaft having a gear wheel 52 thereon. The gear wheel 52 is located in the lower portion of the chamber 30 within the base portion 22 and alongside the shaft 42.

The gear wheel 52 includes teeth to engage in notches 53 provided in a side of the shaft 42. Operation of the drive motor 50 rotates the gear 52 and thereby causes translational movement of the shaft 42 between the retracted and extended positions.

The plug 10 is provided with a timer within the chamber 30. The timer is provided in connection with the drive motor 50 such that when a predetermined time period has elapsed from commencement of operation, the drive motor 50 is operated to move the shaft 42 from the retracted to the extended position. The timer may be provided on a circuit board 54 within the chamber 30. A power source, such as a battery 56, is also provided within the chamber 30 to power the drive motor 50 and the circuitry. In the embodiment shown, the battery 56 is located in the upper portion of the chamber 30 alongside the drive motor 50.

The plug 10 is provided with a start device. In the embodiment shown in the drawings, the start device comprises a button 58 provided on the upper portion 24 of the body 12. When the button 58 is depressed, the shaft 42 is moved from the extended position (as shown in FIG. 7b) to the retracted position (as shown in FIG. 7a) and operation of the timer commences. The timer may operate in one or more modes where the time period before the shaft 42 is moved to the extended position varies. The modes may be selected by the manner in which the button 58 is depressed. For example, multiple presses may be used to operate the timer for a longer period.

In the embodiment shown, the button 58 is provided on one of the second planar wall portions 78. The plug 10 is provided also with indicator lights 59 to indicate the time period which has been selected for operation. The indicator lights 59 are provided on the second planar wall portion 78 alongside the start button 58. In the embodiment shown, there are provided four such indicator lights 59. The number of lights 59 illuminated indicates multiples of the time period selected. For example, if the time period is set to fifteen minutes, a single illuminated light indicates fifteen minutes before the shaft 42 is extended, two illuminated light indicates thirty minutes before the shaft 42 is extended, three illuminated light indicates forty-five minutes before the shaft 42 is extended and four illuminated light indicates an hour before the shaft 42 is extended.

The upper portion 24 is provided with a cover 80 in the embodiment shown. The cover 80 extends across and seals over the upper portion 24 of the body 12 such that the body 12 of the plug 10 is waterproof. The cover 80 comprises a flexible resilient material and extends around the lower end 27 of the upper portion 24 of the body 12 across the shoulder portion 32. The lower end of the cover 80 thereby engages against the rim portion 20 of the outlet 14 to assist with sealing the outlet 14.

The plug 10 is provided also with a charging device 60 for charging the battery 56. In the embodiment shown, the charging device 60 comprises a cradle 62 having a power cable 64 such that the base portion 22 of the plug 10 may be received in the cradle 62. The base wall 28 of the base portion 22 is provided with contacts 66 to engage with contacts in the cradle 62 to charge the battery 56 when placed in the cradle 62.

In use, the plug 10 can be used to ensure that water within a bath is drained within a predetermined time period. The plug 10 is activated by pressing the start button 56 to select the desired time period, which withdraws the shaft 42 to the retracted position. The plug 10 is then placed into the outlet 14 as shown in FIG. 8b. The timer operates from depression of the button 58, during which time the bath would be in use. When the time period has expired, the shaft 42 is moved to the extended position, which dislodges the body 12 of the plug 10 from the outlet 14. The water may therefore not be inadvertently left in the bath, as the plug 10 will open the outlet 14 at the expiration of the time period, allowing the water to drain from the bath.

FIGS. 12 and 13 show a second embodiment of a plug 10 in accordance with the present invention. The plug of FIGS. 12 and 13 is similar to the previous embodiment and like reference numerals are used to denote like parts. The plug 10 includes an alternate shape for the upper portion 24. The upper portion 24 is dome shaped and the start button 58 is provided centrally on an upper surface of the dome shaped upper portion 24.

This embodiment is shown without indicator lights, however it will be appreciated that indicator lights may be used with this configuration.

The plug 10 may also incorporate a temperature sensor (not shown). The temperature sensor is provided to sense the temperature of the water within the bath. The plug 10 may include also an alert provided to indicate that the temperature of the water is above a particular value. The alert may comprise, for example, a particular illumination sequence of the indicator lights 59.

The body 12 of the plug 10 may be constructed to have a density near to or below that of water. By setting the density near or below 1 kg/m³, the plug 10 will be retained in place in the outlet 14 by the weight of water but may move upwardly away from the outlet 14 when operation of the actuator 40 allows water to flow through the outlet. The motion of the shaft 42 may be sufficient to cause the plug 10 to move upwardly and away such that the body 12 is next to the outlet. Alternatively, the body 12 may have buoyancy sufficient to float upwardly on disengagement from the outlet 14.

The plug 10 may include also a motion sensor (not shown). The motion sensor is provided within the body 12 to sense movement within the bath. The motion sensor is provided in connection with the timer such that the time period before the shaft 42 is extended is set to commence only when no motion is detected within the bath. If no motion is detected and operation of the timer commences, the timer may be reset on detection of motion.

It will be readily apparent to persons skilled in the relevant arts that various modifications and improvements may be made to the foregoing embodiments, in addition to those already described, without departing from the basic inventive concepts of the present invention.

What is claimed is:

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. A plug comprising:
a body being receivable in relation to an outlet of a bath to prevent water flow;
an actuator within the body moveable from a retracted position to an extended position; and
a timer operable such that when a time period has elapsed from activation of the timer, the actuator moves from the retracted to the extended position;
wherein in the extended position, the actuator moves the body of the plug to disengage the plug from the outlet such that water may flow outwardly through the outlet.

23. The plug in accordance with claim 22, wherein the body includes a base portion receivable in the outlet and an upper portion located in use above the outlet.

24. The plug in accordance with claim 23, wherein the actuator comprises a shaft provided within a chamber in the base portion of the body such that, in the extended position, a first end of the shaft protrudes outwardly through a port in the base portion.

25. The plug in accordance with claim 24, wherein the first end of the shaft includes an angled portion to engage with an upper edge of a cylindrical outer wall of the outlet to lift the body of the plug relative to the outlet.

26. The plug in accordance with claim 23, wherein the angled portion comprises a planar face such that, in the extend position, an upper edge thereof is located further away from the base portion than a lower edge thereof.

27. The plug in accordance with claim 23, wherein the base portion comprises a cylindrical side wall and a circular base wall and wherein the shaft is located adjacent and parallel to the base wall and the port is provided in the side wall.

28. The plug in accordance with claim 22, further comprising:
a drive motor provided within an upper portion of the chamber; and
a gear wheel provided on a drive shaft of the drive motor, the gear wheel being located adjacent the shaft;
wherein teeth on the gear wheel engage with notches provided in a side of the shaft such that operation of the drive motor rotates the gear and thereby causes translational movement of the shaft between the retracted and extended positions.

29. The plug in accordance with claim 22, wherein the base portion and the upper portion of the body are cylindrical in shape and a lower end of the upper portion is wider than the base portion such that a shoulder portion is defined between the base portion and upper portion, the shoulder portion resting on top of a rim of the outlet to prevent flow of fluid.

30. The plug in accordance with claim 22, wherein a button is provided such that operation of the button causes the shaft to move from the extended position to the retracted position and operation of the timer to commence.

31. The plug in accordance with claim 30, wherein an upper end of the upper portion includes cut out portions on opposed upper sides thereof defining first planar wall portions extending vertical downwardly from an upper end of the upper portion on opposed sides of the upper portion, and second planar wall portions extending horizontally outwardly from lower ends of the first planar wall portions.

32. The plug in accordance with claim 31, wherein the start button is provided on one of the second planar wall portions.

33. The plug in accordance with claim 30, wherein the time period of operation may be selected by multiple presses of the button and a plurality of indicator lights are provided to indicate the time period which has been selected.

34. The plug in accordance with claim 33, wherein the indicator lights are provided on the second planar wall portion alongside the start button.

35. The plug in accordance with claim 34, wherein the upper portion is provided with a cover extending across and sealing over the upper portion of the body such that the body of the plug is waterproof.

36. The plug in accordance with claim 35, wherein the cover comprises a flexible resilient material and extends around a lower end of the upper portion of the body across the shoulder portion to engage against and seal the outlet.

37. The plug in accordance with claim 24, wherein one or more seals are provided adjacent the first end of the shaft to engage between an inner surface of the port and an outer surface of the shaft to prevent ingress of water through the port into the chamber.

38. The plug in accordance with claim 22, wherein the plug includes a battery to power movement of the actuator and a base wall of the base portion is provided with contacts to engage with contacts in a cradle of a charging device when the plug is placed in the cradle in order to charge the battery.

39. The plug in accordance with claim 22, wherein a temperature sensor is provided to sense the temperature of the water within the bath and an alert is provided to indicate that the temperature of the water is above a particular value.

40. The plug in accordance with claim 22, wherein the body has a density near to or below that of water such that motion of the actuator to the extended position is sufficient to cause the plug to move upwardly and away from the outlet.

41. The plug in accordance with claim 22, wherein the plug includes a motion sensor to sense movement within the bath, the motion sensor being in communication with the timer such that the time period before the actuator is extended is set to commence when no motion is detected within the bath.

42. A plug comprising:
a body being receivable in relation to an outlet of a bath to prevent water flow;
a timer operable such that when a time period has elapsed from activation of the timer, the body or a portion of the body is disengaged from the outlet to allow water to flow through the outlet; and
a motion sensor provided to detect movement within the bath;
wherein the time period before the body or the portion of the body is disengaged from the outlet commences when no motion is detected within the bath.
